(19) United States
(12) Patent Application Publication
(10) Pub. No.: US 2010/0007365 A1
(43) Pub. Date: Jan. 14, 2010

(54) SOCKET FOR DOUBLE ENDED PROBE, DOUBLE ENDED PROBE, AND PROBE UNIT

(75) Inventors: Toshihiro Ishizuka, Kawasaki (JP); Takeo Ogawa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/496,043

(22) Filed: Jul. 1, 2009

(30) Foreign Application Priority Data
Jul. 14, 2008 (JP) 2008-182796

(51) Int. Cl. G01R 1/067; G01R 31/02; H01R 13/73

(52) U.S. Cl. 324/761; 439/894

(57) ABSTRACT

A socket for a double ended probe with a first probe and a second probe includes a hollow pipe member housing the first probe and the second probe, the first probe and the second probe are arranged in an axial direction of the socket, and the socket includes an abutment holding the first probe and the second probe at predetermined positions on an inner side of the hollow pipe member.

### CROSS-REFERENCE TO RELATED APPLICATIONS

This application is based upon and claims the benefit of priority of the prior Japanese Patent Application No. 2008-182796, filed on Jul. 14, 2008, the entire contents of which are incorporated herein by reference.

### FIELD

The embodiment discussed herein is related to probes, and in particular, relates to a double ended probe in which contact pins extend out from the both ends of a socket.

### BACKGROUND

When an electrical test for a semiconductor device is performed, a probe is used to connect an electrode of the semiconductor device to a test circuit. Typical probes include spring probes in which pins can be moved in the axial direction.

In a spring probe, a plunger on which a contact pin is formed is urged by a spring such as a coil spring and held in a barrel so as to be movable. Spring probes include a single ended spring probe in which a contact pin extends out only from one end of a barrel and a double ended spring probe in which contact pins extend out from the both ends of a barrel. In general, a double ended spring probe is used to establish electrical contact with both an electrode of a semiconductor device and an electrode pad of a test board.

In many cases, a double ended spring probe is used in a state in which one end of the double ended spring probe is connected to a test circuit board, and a semiconductor device on the side of the other end is changed in turn. Thus, while a contact pin connected to the test circuit board is left intact once being connected to the test circuit board, a contact pin connected to the semiconductor device is repeatedly connected to (brought into contact with) and detached from the semiconductor device every time the semiconductor device is tested.

Thus, the contact pin connected to the semiconductor device may be worn much earlier than the contact pin connected to the test circuit board. Moreover, when contact and detachment are repeated, absorption of, for example, foreign substances may occur, or corrosion may advance. In such cases, the contact pin connected to the semiconductor device needs to be replaced with a new one.

However, since a known double ended spring probe is formed as one piece, it is impossible to change only a contact pin at one end. Thus, when the contact pin connected to the semiconductor device needs to be replaced with a new one, the entire double ended spring probe needs to be replaced with a new one. That is, even when the contact pin connected to the test circuit board can be still used, the contact pin connected to the test circuit board is changed, together with the contact pin connected to the semiconductor device.

Accordingly, a probe for inspecting a board is proposed (for example, refer to Japanese Laid-open Patent Publication No. 9-113536). In the probe, only the tip of a contact pin can be changed. The probe can be divided into a main probe part on the side of the tip of the contact pin that establishes contact and an auxiliary probe part, and the main probe part can be attached to and detached from the auxiliary probe part. Thus, only the main probe part can be changed.

When an arrangement in which only the tip of the contact pin can be changed is adopted, a holding mechanism that holds the tip of the contact pin so that the tip of the contact pin can be detached is necessary. When the probe is used alone, enough space is available around the probe, and thus such a holding mechanism can be provided.

However, in a test for semiconductor devices, since many probes are brought into contact with many electrodes arranged close to each other at the same time, the probes need to be disposed close to each other. In this case, a problem exists in that it is difficult to provide space, in which a holding mechanism can be provided, around each of the probes. Moreover, when a holding mechanism is provided for each of the probes, the cost of manufacturing the probes increases. Moreover, another problem exists in that, since many probes are provided, the total cost of manufacturing all the probes significantly increases.

Accordingly, development of a double ended probe, having a simple structure, in which only a contact pin at one end can be changed is desired.

### SUMMARY

According to an aspect of the invention, a socket for a double ended probe with a first probe and a second probe includes a hollow pipe member housing the first probe and the second probe, the first probe and the second probe are arranged in an axial direction of the socket, and the socket includes an abutment holding the first probe and the second probe at predetermined positions on an inner side of the hollow pipe member. The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a sectional view of a double ended probe according to a first embodiment;

FIG. 2 is a sectional view of a socket illustrated in FIG. 1;

FIG. 3 is a side view of the socket illustrated in FIG. 1;

FIG. 4 is a side view of a modification of the socket illustrated in FIG. 1;

FIGS. 5A to 5D are sectional views illustrating spring probes that include contact pins of different shapes;

FIG. 6 is a sectional view of a modification of the double ended probe illustrated in FIG. 1;

FIG. 7 is a sectional view of a socket of a double ended probe according to a second embodiment;

FIG. 8 is a sectional view of a modification of the socket illustrated in FIG. 7; and

FIG. 9 is a perspective view of a probe unit in which double ended probes are built.

### DESCRIPTION OF EMBODIMENTS

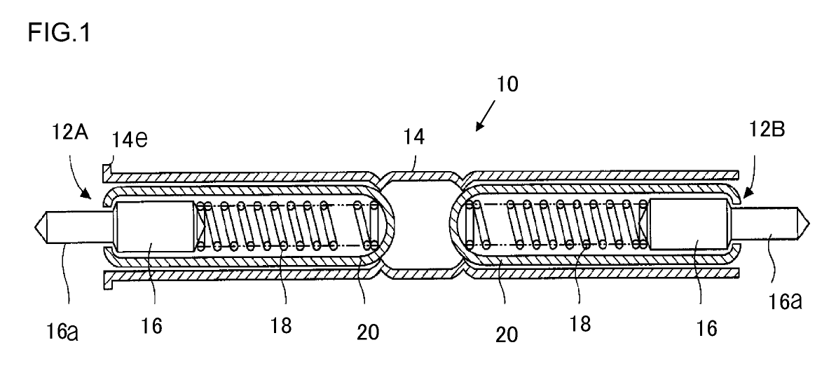

A double ended probe according to a first embodiment will now be described with reference to FIG. 1. FIG. 1 is a sectional view of a double ended probe 10 according to the first embodiment.

The double ended probe 10 includes probes 12A and 12B and a socket 14 in which the probes 12A and 12B are housed. The probes 12A and 12B are inserted into the socket 14 and fixed so that the probes 12A and 12B are arranged in mutually opposite directions.

In the first embodiment, each of the probes 12A and 12B is a probe that is generically called a spring probe. Specifically, each of the probes 12A and 12B is a probe in which a plunger 16 on the tip of which a contact pin 16a is provided and a coil spring 18 that urges the plunger 16 are housed in a barrel 20.

The probes 12A and 12B are housed in the socket 14 so that the respective contact pins 16a extend out from the both ends of the socket 14 and can be moved in the axial direction. When the contact pin 16a is pushed, the plunger 16 penetrates into the socket 14, compressing the coil spring 18. The resilience of the coil spring 18 at this time is applied to the contact pin 16a as the contact pressure.

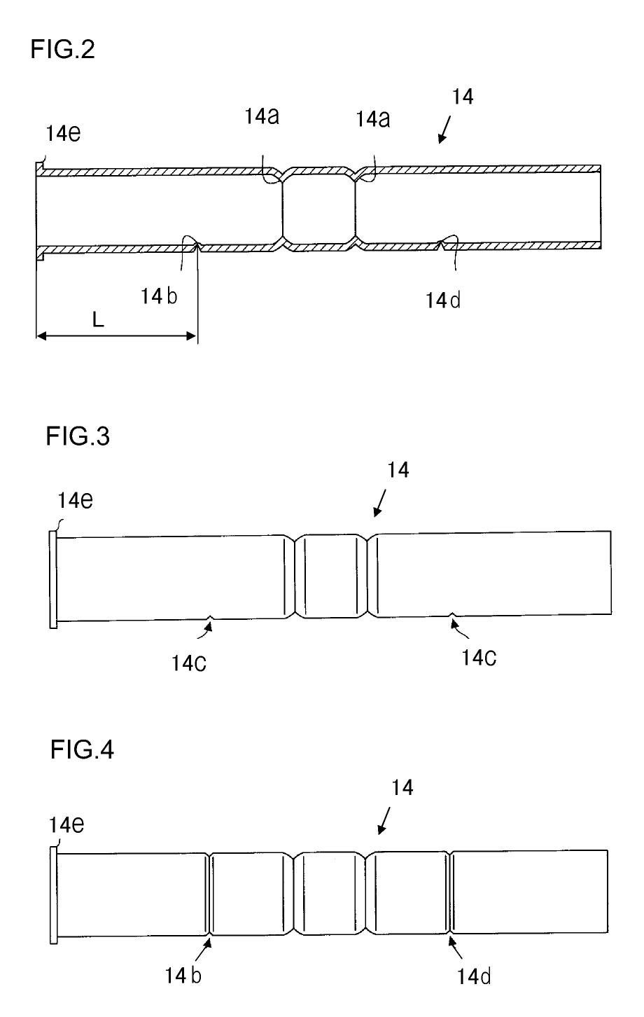

FIG. 2 is a sectional view of the socket 14. The socket 14 will next be described also referring to FIG. 2. The socket 14 is composed of, for example, a hollow pipe member having a wall thickness of several tens of micrometers. It is preferable that the material of the pipe member be an electrically well conducting metal. For example, phosphor bronze or beryllium copper is suitable for the material of the pipe member. Moreover, for example, a pipe member produced by plating stainless steel with gold may be used.

It is preferable that the inner diameter of the socket 14 be substantially equal to the outer diameter of the barrel 20 of each of the probes 12A and 12B and be such that the probes 12A and 12B can be lightly pressed into the socket 14. However, considering variation in the outer diameter of the barrel 20 and variation in the inner diameter of the socket 14, it is preferable that the inner diameter of the socket 14 be slightly larger than the outer diameter of the barrel 20, a protrusion be provided on the inner surface of the socket 14, as described below, and the barrel 20 be pressed into the socket 14.

The probe 12A is inserted into the socket 14 from one end of the socket 14, and the probe 12B is inserted into the socket 14 from the other end. The probes 12A and 12B are inserted into the socket 14 so that the probes 12A and 12B are arranged in mutually opposite directions. Protrusions 14a that inwardly protrude from the inner wall of the socket 14 are provided near the center of the socket 14. When the respective back ends of the probes 12A and 12B inserted into the socket 14 are brought into contact with the protrusions 14a, the probes 12A and 12B cannot be further inserted into the socket 14. That is, the probes 12A and 12B are stopped by being applied to the protrusions 14a to be positioned in the socket 14. In other words, each of the protrusions 14a functions as an abutment. The respective positions of the protrusions 14a are such that the barrel 20 of each of the probes 12A and 12B is housed in the socket 14, and the contact pin 16a extends out from the socket 14. Moreover, the protrusions 14a are provided at positions such that the probes 12A and 12B are not brought into contact with each other in the socket 14. The protrusions 14a can be readily formed by drawing the pipe member constituting the socket 14.

Small protrusions 14b that inwardly protrude from the inner wall of the socket 14 are provided in the socket 14 (refer to FIG. 2). The protrusions 14b are parts corresponding to dents 14c formed by punching the outer surface of the pipe member constituting the socket 14. Each of the protrusions 14b may be provided at a position on a perimeter of the pipe member, as illustrated in FIG. 3, or may be provided at a plurality of positions on the perimeter. Alternatively, constrictions 14d may be formed by deforming perimeters of the pipe member by drawing so as to form the protrusions 14b shaped like rings on the inner wall of the socket 14 at portions of the constrictions 14d, as illustrated in FIG. 4. The protrusions 14b are formed so that the height of the protrusions 14b is such that the barrel 20 of each of the probes 12A and 12B is appropriately clamped.

The position of each of the protrusions 14b in the axial direction of the socket 14 is between an end of the socket 14 and a corresponding one of the protrusions 14a serving as a stopper to stop insertion and is such that the protrusion 14b is brought into contact with the barrel 20. However, when a portion of the barrel 20 in which the plunger 16 is moved is deformed, the plunger 16 may not be moved smoothly. Thus, it is preferable that each of the protrusions 14b be located at a position, on the side of the center of the socket 14, such that the distance between an end of the socket 14 and the position is equal to or larger than the total length of the plunger 16 including the contact pin 16a. That is, distance L between an end of the socket 14 and each of the protrusions 14b is set so as to be equal to or larger than the maximum stroke of the plunger 16 moving when the contact pin 16a is pushed. Thus, even when the barrel 20 is slightly deformed by a corresponding one of the protrusions 14b, the movement of the plunger 16 is not affected.

A collar 14e is provided at one end of the socket 14. The collar 14e is a part the outer diameter of which is slightly larger than the outer diameter of the socket 14 and functions as a stopper when the socket 14 is inserted into a through hole of a board, as described below.

In the double ended probe 10 having the aforementioned structure, a probe at one end (for example, the probe 12A) is brought into contact with an electrode of a semiconductor device, and a probe at the other end (for example, the probe 12B) is brought into contact with an electrode pad of a test circuit board. Since the socket 14 is composed of a pipe member of electrically well conducting material, the probes 12A and 12B are electrically continuous via the socket 14. Thus, the electrode of the semiconductor device can be electrically connected to the electrode pad of the test circuit board.

Since the probes 12A and 12B are lightly pressed into the socket 14 to be held, the probes 12A and 12B can be readily removed from the socket 14. Thus, for example, when only the contact pin 16a of the probe 12A becomes unusable due to abrasion, the contact pin 16a can be readily changed by removing only the probe 12A from the socket 14 and inserting a new probe into the socket 14.

Moreover, each of the probes 12A and 12B has a simple structure in which each of the probes 12A and 12B is supported by the socket 14 composed of a thin-walled pipe member, and the outer diameter of the double ended probe 10 is slightly larger than the outer diameter of the probes 12A and 12B. Thus, a large number of the double ended probes 10 can be provided in a unit area, and a semiconductor device that includes electrodes with a small pitch can be supported.

In the double ended probe 10 illustrated in FIG. 1, spring probes including the contact pins 16a of the same shape are used as the probes 12A and 12B. The shape of the contact pin 16a may be changed according to the usage.

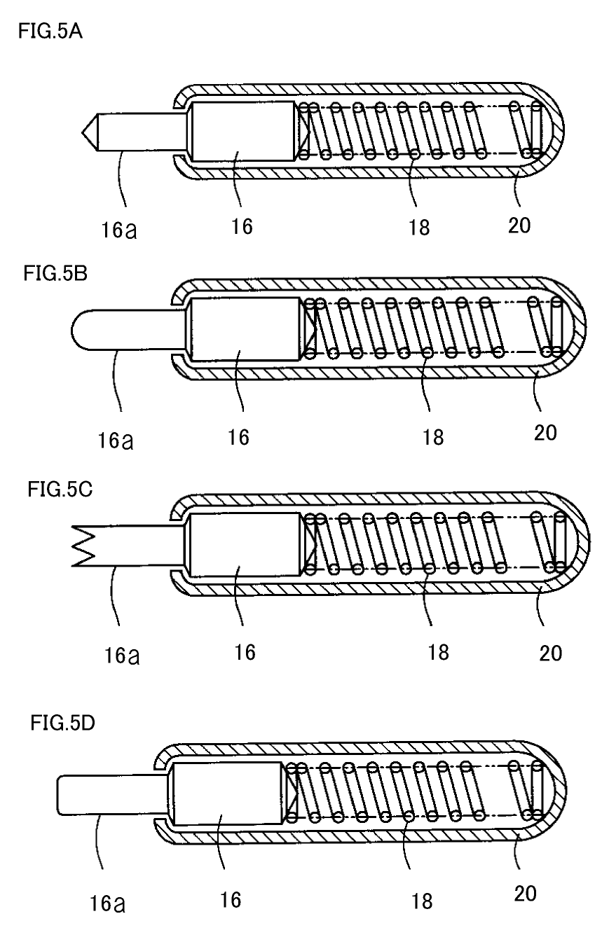

FIGS. 5A to 5D are sectional views illustrating spring probes that include the contact pins 16a of different shapes. FIG. 5A illustrates a spring probe that includes the contact pin 16a, the tip of which is sharpened into a conical shape. FIG. 5B illustrates a spring probe that includes the contact pin 16a, the tip of which is rounded into a hemispherical shape. FIG. 5C illustrates a spring probe that includes the contact pin 16a, the tip of which is formed into a crown shape. FIG. 5D illustrates a spring probe that includes the contact pin 16a, the tip of which is flat.

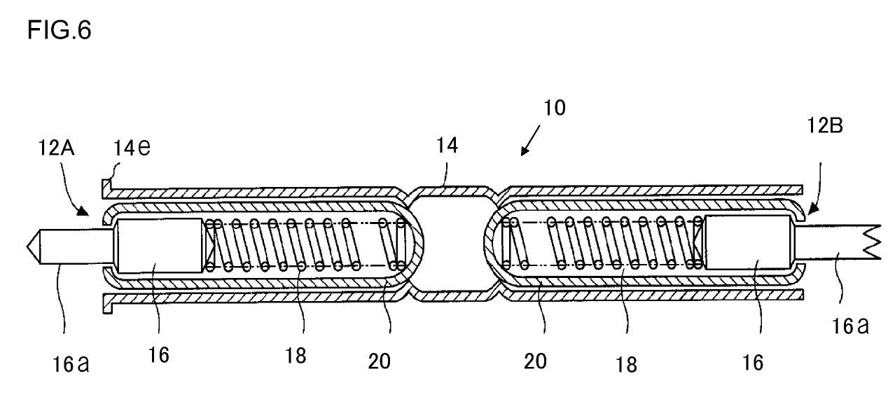

A double ended probe that includes the contact pins 16a of different types at the both ends thereof can be readily constructed merely by selecting a combination of ones of the spring probes illustrated in FIGS. 5A to 5D and inserting the combination of the spring probes into the socket 14. FIG. 6 is a sectional view illustrating an exemplary double ended probe 10 that includes contact pins 16a of different shapes at the both ends thereof. In the example illustrated in FIG. 6, the spring probe illustrated in FIG. 5A is used as the probe 12A, and the spring probe illustrated in FIG. 5C is used as the probe 12B.

A double ended probe according to a second embodiment will now be described.

The basic structure of the double ended probe according to the second embodiment is similar to that of the double ended probe according to the first embodiment. The double ended probe according to the second embodiment is different from the double ended probe according to the first embodiment in the structure of the socket. Thus, only the structure of the socket of the double ended probe according to the second embodiment will be described here.

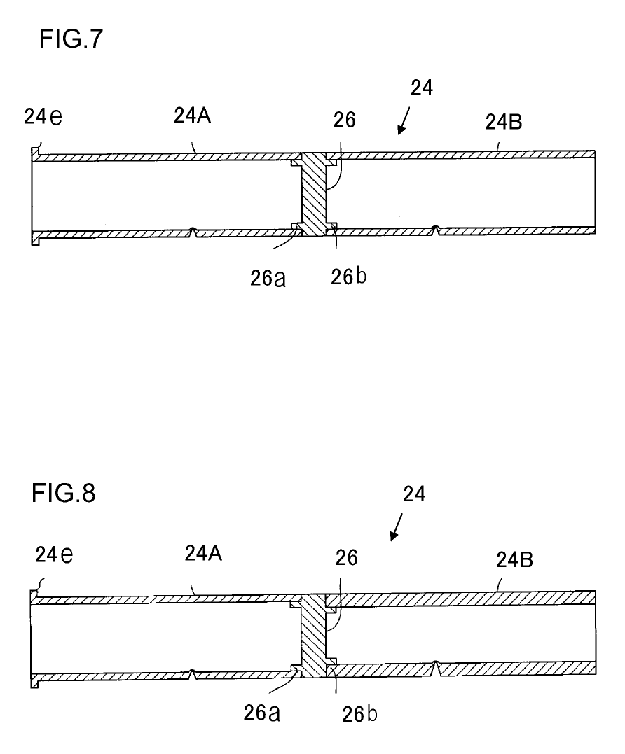

FIG. 7 is a sectional view of a socket 24 of the double ended probe according to the second embodiment. Pipe members 24A and 24B are joined into one piece by a coupling part 26 to form the socket 24. The pipe members 24A and 24B correspond to two pieces into which the pipe member constituting the aforementioned socket 14 is divided. A collar 24e is provided at one end of the socket 24.

The coupling part 26 has the same outer diameter as the pipe members 24A and 24B and includes, at the both ends thereof, engaging parts 26a and 26b with which the pipe members 24A and 24B respectively engage. The socket 24 is constructed by engaging the pipe members 24A and 24B with the engaging parts 26a and 26b respectively.

The coupling part 26 functions as an abutment to which the probes 12A and 12B are applied when the probes 12A and 12B are inserted into the socket 24. That is, when the probes 12A and 12B are inserted from an end of the pipe member 24A and an end of the pipe member 24B respectively, the respective back ends of the probes 12A and 12B are applied to the coupling part 26 and cannot be further inserted. This position is the predetermined position of each of the probes 12A and 12B illustrated in FIG. 1.

In this case, probes having different diameters can be built in by changing the inner diameter of the pipe member 24A or 24B, as illustrated in FIG. 8.

The double ended probe including the socket 24 has the same effects as the double ended probe 10 according to the first embodiment. That is, since the probes 12A and 12B are lightly pressed into the socket 24 to be held, the probes 12A and 12B can be readily removed from the socket 24. Thus, for example, when only the contact pin 16a of the probe 12A becomes unusable due to abrasion, the contact pin 16a can be readily changed by removing only the probe 12A from the socket 24 and inserting a new probe into the socket 24.

Moreover, each of the probes 12A and 12B has a simple structure in which each of the probes 12A and 12B is supported by the socket 24 composed of a thin-walled pipe member, and the outer diameter of the double ended probe is slightly larger than the outer diameter of the probes 12A and 12B. Thus, a large number of the double ended probes can be provided in a unit area, and a semiconductor device that includes electrodes with a small pitch can be supported.

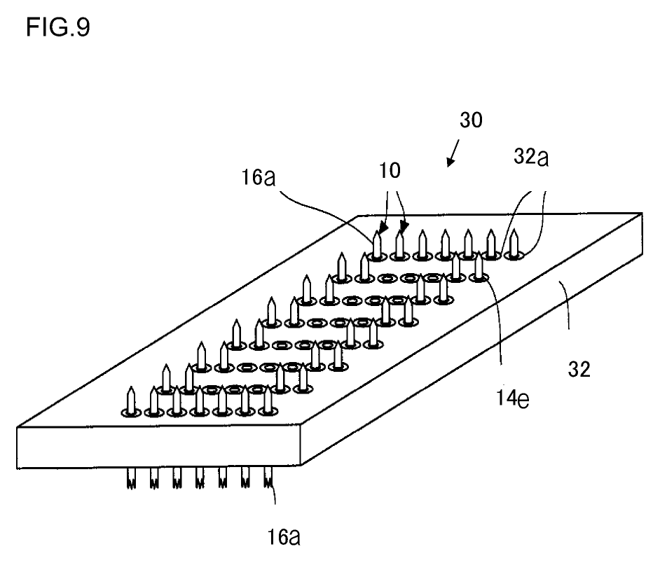

The aforementioned double ended probe is built in a probe unit 30, as illustrated in FIG. 9. In the probe unit 30, the aforementioned double ended probe (for example, the double ended probe illustrated in FIG. 6) is built in each of the plurality of through holes 32a formed in a board 32. The inner diameter of the through holes 32a is slightly larger than the outer diameter of the sockets 14 and 24 of the double ended probe and is smaller than the outer diameter of the collar 14e of the socket 14 and the collar 24e of the socket 24. Thus, when the sockets 14 and 24 of the double ended probes are inserted into one of the through holes 32a from above, the sockets 14 and 24 are stopped at the collars 14e and 24e, respectively, so that the double ended probes are held in the through hole 32a. In this case, the arrangement of the plurality of through holes 32a is the same as the arrangement of electrodes of a semiconductor device subjected to a test.

According to the aforementioned double ended probe, only a probe at one end of a socket can be readily removed from the socket. Thus, only a probe that needs to be changed can be readily and quickly changed. Moreover, a socket is composed of a thin-walled cylindrical member, has a diameter that is slightly larger than the diameter of a probe, and does not require large space. Thus, the aforementioned double ended probe can be disposed in a manner similar to that in which an existing double ended probe is disposed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A socket for a double ended probe with a first probe and a second probe, comprising:
a hollow pipe member housing the first probe and the second probe, the first probe and the second probe arranged in an axial direction of the socket; and
an abutment holding the first probe and the second probe at predetermined positions on an inner side of the hollow pipe member.

2. The socket according to claim 1, wherein the abutment is a first protrusion on an inner wall, the first protrusion being formed by deforming the hollow pipe member.

3. The socket according to claim 1, wherein the hollow pipe member includes a first pipe member that houses the first probe and a second pipe member that houses the second probe, and
the first pipe member and the second pipe member are connected at the abutment into one piece.

4. The socket according to any claims 1, wherein second protrusions fixing the first probe and the second probe are provided on an inner surface of the hollow pipe member.

5. The socket according to claim 4, wherein the second protrusions are formed by deforming the hollow pipe member from an outer side of the hollow pipe member.

6. The socket according to claims 1, wherein a collar is provided at one end of the socket, an outer diameter of the collar being larger than an outer diameter of the socket.

7. A double ended probe comprising:
a first probe;
a second probe; and
a socket building in the first probe and the second probe, the socket having a hollow pipe member housing the first probe and the second probe, the first probe and the second probe arranged in an axial direction of the socket, the socket having an abutment holding the first probe and the second probe at predetermined positions on an inner side of the hollow pipe member,
wherein the first probe and the second probe are inserted into the socket from mutually opposite ends of the socket, and a tip of the first probe and a tip of the second probe extend out from both ends of the socket,

8. The double ended probe according to claim 7, wherein each of the first probe and the second probe is a spring probe in which a plunger a tip of which is formed as a contact pin and a spring that urges the plunger are housed in a barrel.

9. The double ended probe according to claim 8, wherein protrusions fixing the first probe and the second probe are provided on an inner surface of the hollow pipe member, and the protrusions are located at positions, on a center side of the socket, such that each of distances between both ends of the socket and the positions of the protrusions is larger than a corresponding one of lengths of the respective plungers of the first probe and the second probe.

10. The double ended probe according to claim 8, wherein a shape of a contact pin of the first probe differs from a shape of a contact pin of the second probe.

11. A probe unit comprising:
a double ended probe including
a first probe,
a second probe, and
a socket building in the first probe and the second probe, the socket having a hollow pipe member housing the first probe and the second probe, the first probe and the second probe arranged in an axial direction of the socket, the socket having an abutment holding the first probe and the second probe at predetermined positions on an inner side of the hollow pipe member, wherein the first probe and the second probe are inserted into the socket from mutually opposite ends of the socket, and a tip of the first probe and a tip of the second probe extend out from both ends of the socket; and
a board that includes a plurality of through holes supporting the double ended probes.
